(19) United States
(12) Patent Application Publication
(10) Pub. No.: US 2012/0293159 A1
(43) Pub. Date: Nov. 22, 2012

(54) VOLTAGE TESTING CIRCUIT

(75) Inventor: YONG-ZHAO HUANG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/172,849

(22) Filed: Jun. 30, 2011

(30) Foreign Application Priority Data
May 18, 2011 (CN) 201110128939.2

(51) Int. Cl. G01R 19/00

(52) U.S. Cl. 324/76.11

(57) ABSTRACT

A voltage testing circuit includes a voltage input terminal, an LED, a first reference resistor, a transistor, a current-limiting resistor, a second reference resistor, and a 3-terminal adjustable regulator. The transistor includes an emitter, a base connected to the voltage input terminal through the first reference resistor, and a collector connected to the voltage input terminal. The current-limiting resistor is connected between the emitter and an anode of the LED. The second reference resistor is connected between the voltage input terminal and ground. The 3-terminal adjustable regulator includes a positive terminal grounded, a negative terminal connected to a cathode of the LED, and a controlling terminal connected to the voltage input terminal through the second reference resistor. The LED emits light according to voltage of the voltage input terminal.

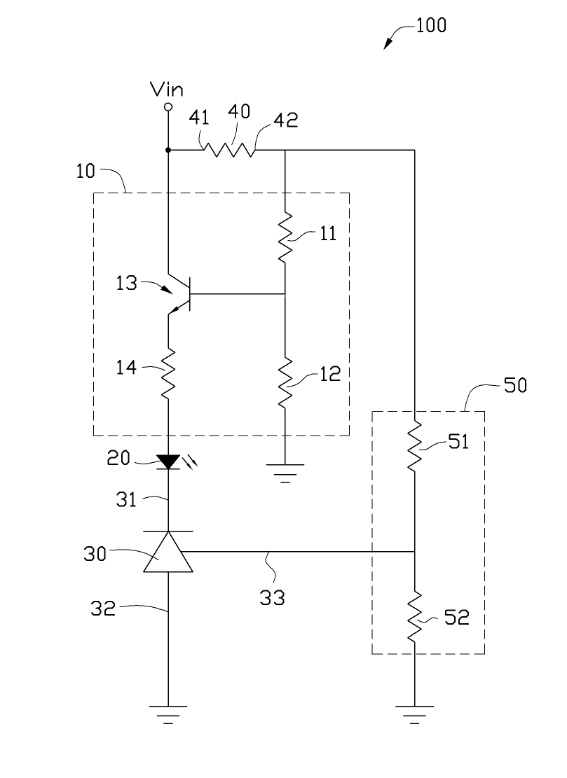

### BACKGROUND

1. Technical Field

The present disclosure relates to a voltage testing circuit.

2. Description of Related Art

Circuits include a number of nodes. Voltages of some of the nodes will affect performance of the circuit. In other words, if the voltages of some nodes are less than the corresponding normal values of the nodes, the circuits will not work normally. Users usually use voltmeters to measure the voltages of the nodes, which is inconvenient.

Therefore, it is desirable to provide a voltage testing circuit that can overcome the above-mentioned limitations.

### BRIEF DESCRIPTION OF THE DRAWING

Many aspects of the embodiments should be better understood with reference to the following drawing. The components in the drawing are not necessarily drawn to scale, the emphasis instead being placed upon clearly illustrating the principles of the present disclosure.

The drawing is a schematic view of a voltage testing circuit, according to an exemplary embodiment.

### DETAILED DESCRIPTION

Referring to the drawing, a voltage testing circuit 100, according to an embodiment, can be used to test a voltage of a node (not shown). The voltage of the node can be compared to determined if the voltage is greater than or equal to a normal voltage of the node. The voltage testing circuit 100 includes a voltage input terminal Vin, a switching unit 10, a light-emitting diode (LED) 20, a 3-terminal adjustable regulator 30, a dropping resistor 40, and a reference unit 50.

The voltage input terminal Vin is electrically connected to a node of a circuit (not shown). The dropping resistor 40 includes a first end 41 and a second end 42. The first end 41 is electrically connected to the voltage input terminal Vin.

The switching unit 10 includes a first reference resistor 11, a first pull-down resistor 12, a transistor 13, and a current-limiting resistor 14. A base of the transistor 13 is electrically connected to the second end 42 through the first reference resistor 11. The base of the transistor 13 is also electrically connected to ground through the first pull-down resistor 12. A collector of the transistor 13 is electrically connected to the voltage input terminal Vin. An emitter of the transistor 13 is electrically connected to an anode of the LED 20 through the current-limiting resistor 14. In this embodiment, the transistor 13 is a bipolar junction transistor (BJT).

The 3-terminal adjustable regulator 30 includes a negative terminal 31, a positive terminal 32, and a control terminal 33. The negative terminal 31 is electrically connected to a cathode of the LED. The positive terminal 32 is grounded. The control terminal 33 is electrically connected to the reference unit 50.

The reference unit 50 includes a second reference resistor 51 and a second pull-down resistor 52. The control terminal 33 is electrically connected to the second end 42 through the second reference resistor 51. The control terminal 33 is also grounded through the second pull-down resistor 52.

In one exemplary non-limiting embodiment, the normal voltage of the node is about 6 V. The voltage drop across the dropping resistor 40 is about 1 V. The resistance of the first reference resistor 11 is about 1 KΩ, the resistance of the first pull-down resistor 12 is about 4 KΩ, the resistance of the second reference transistor 51 is about 4 KΩ, the resistance of the second pull-down resistor 52 is about 4 KΩ. When the voltage of the base of the transistor 13 is about 4 V, the collector of the transistor 13 is electrically connected to the emitter of the transistor 13. When the voltage of the controlling terminal 33 is about 2.5 V, the negative terminal 31 is electrically connected to the positive terminal 32. The 3-terminal adjustable regulator 30 can be a TL431 regulator.

In use, when the voltage of the node is greater than or equal to 6 V, the voltage of the second end 42 is 5 V, the voltage of the controlling terminal 33 is equal to the voltage drop of the second pull-down resistor 52. Because the resistance of the second reference resistor 51 is equal to the second pull-down resistor 52, the voltage of the second pull-down resistor 52 is about 2.5 V, and thus the voltage of the control terminal 33 is about 2.5 V, the negative terminal 31 is electrically connected to the positive terminal 32. At the same time, the voltage of the base of the transistor 13 is equal to the voltage drop of the first pull-down resistor 12, and thus the voltage of the base of the transistor 13 is 4 V, the collector of the transistor 13 is electrically connected to the emitter of the transistor 13. The anode of the LED 20 is electrically connected to the voltage input terminal Vin through the transistor 13 and the current-limiting resistor 14, the cathode of the LED 20 is grounded through the 3-terminal adjustable regulator 30, and thus the LED 20 emits light. When the voltage of the node is less than the 6 V, the voltage of the control terminal 33 is less than 2.5 V, the negative terminal 31 is electrically disconnected to the positive terminal 32. The voltage of the base of the transistor 13 is less than 4 V, the collector of the transistor 13 is electrically disconnected to the emitter of the transistor 13, and thus the LED 20 will not emit light.

The current-limiting resistor 14 is used for decreasing the current passing through the LED 20 to protect the LED 20, when both of the transistor 13 and the 3-terminal adjustable regulator 30 are respectively electrically conductive.

In other embodiments, the first pull-down resistor 12, and the ground also can be omitted. Accordingly, the resistance of the first reference resistor 11 will be changed to make sure that the collector of the transistor 13 is electrically connected to the emitter of the transistor 13 when the voltage of the node is greater than or equal to the normal voltage of the node.

In other embodiments, the second pull-down resistor 52 and the ground also can be omitted. Accordingly, the resistance of the second reference resistor 51 will be changed to make sure that the negative terminal 31 is electrically connected to the negative terminal 32 when the voltage of the node is greater than or equal to the normal voltage of the node.

In other embodiments, the dropping resistor 40 also can be omitted, and both of the first reference resistor 11 and the second reference resistor 51 are directly electrically connected to the voltage input terminal Vin.

It will be understood that the above particular embodiments are shown and described by way of illustration only. The principles and the features of the present disclosure may be employed in various and numerous embodiments thereof without departing from the scope of the disclosure as claimed. The above-described embodiments illustrate the scope of the disclosure but do not restrict the scope of the disclosure.

What is claimed is:

1. A voltage testing circuit, comprising:
a voltage input terminal;
a light-emitting diode (LED);
a first reference resistor;
a transistor comprising an emitter, a base, and a collector, the collector electrically connected to the voltage input terminal, the base electrically connected to the voltage input terminal through the first reference resistor;
a current-limiting resistor connected between the emitter of the transistor and an anode of the LED;
a second reference resistor electrically connected between the voltage input terminal and ground;
a 3-terminal adjustable regulator comprising:
a positive terminal electrically connected to ground;
a negative terminal electrically connected to a cathode of the LED;
a controlling terminal electrically connected to the voltage input terminal through the second reference resistor.

2. The voltage testing circuit of claim 1, wherein the voltage testing circuit further comprises a dropping resistor electrically connected between the voltage input terminal and the first reference resistor.

3. The voltage testing circuit of claim 1, wherein the voltage testing circuit further comprises a first pull-down resistor, the base of the transistor is grounded through the first pull-down resistor.

4. The voltage testing circuit of claim 1, wherein the voltage testing circuit further comprises a second pull-down resistor, the controlling terminal of the 3-terminal adjustable regulator is grounded through the second pull-down resistor.

5. The voltage testing circuit of claim 1, wherein the 3-terminal adjustable regulator is a TL431 regulator.
